(19) United States
(12) Patent Application Publication
(10) Pub. No.: US 2008/0079040 A1
(43) Pub. Date: Apr. 3, 2008

(54) Transistor And Method For Manufacturing The Same

(75) Inventor: Byung Ho Nam, Daegu-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/758,496

(22) Filed: Jun. 5, 2007

(30) Foreign Application Priority Data
Sep. 29, 2006 (KR) 10-2006-95705

(51) Int. Cl. H01L 21/336; H01L 29/76

(52) U.S. Cl. 257/288; 438/294; 257/E29.226; 257/E21.409

(57) ABSTRACT

A transistor includes a semiconductor substrate including an active region defined by a device isolation layer, gate lines disposed at specified intervals on the active region of the semiconductor substrate, and trenches of a valley structure etched to a specified depth in the semiconductor substrate in contact with end portions of the gate lines.

### CROSS-REFERENCE TO RELATED APPLICATION

The priority of Korean patent application number 10-2006-95705, filed on Sep. 29, 2006, which is incorporated by reference in its entirety, is claimed.

### BACKGROUND OF THE INVENTION

The invention relates to a semiconductor device and, more particularly, to a transistor capable of reducing leakage current and a method for manufacturing the same.

In general, a transistor includes a gate electrode formed in a line on a semiconductor substrate (hereinafter, referred to as a “gate line”) and source/drain regions formed by implanting n-type or p-type conductive impurities into the semiconductor substrate exposed at both sides of the gate electrode.

Along with the trend of high integration of semiconductor devices, the width of the gate line has become smaller. As the gate line width becomes smaller, when a voltage is applied from a source to a drain of the transistor, leakage current may be generated at an end portion of the gate line due to the Hot Electron Induced Punchthrough (HEIP) effect, thereby degrading the operational characteristics.

Accordingly, the end portion of the gate line, i.e., an edge portion adjacent to a device isolation layer, in a peripheral circuit region is formed in a tab shape having a width larger than the gate line width in an active region to prevent the leakage current from being generated due to the HEIP effect.

FIGS. 1A to 1C are diagrams for explaining a conventional transistor. FIGS. 1B and 1C are cross sectional views of the transistor taken along lines A-A′ and B-B′ in FIG. 1A.

Referring to FIGS. 1A to 1C, the conventional transistor includes gate lines 20 disposed at specified intervals on an active region 10 of a semiconductor substrate. An end portion 30 of each gate line 20 in contact with the active region 10 adjacent to a device isolation region is formed in a tab shape having a width larger than the line width of the gate line 20. Contact electrodes 40 to be connected to the source/drain regions are disposed on the active region 10 between the gate lines 20. Here, the device isolation region (not shown) is a remaining region except for the active region 10.

In a transistor having the above configuration, the end portion 30 of the gate line 20 (shown in FIG. 1C) is formed in a tab shape having a width larger than the line width of the gate line 20 disposed on the active region 10 (shown in FIG. 1B). That is, the end portion 30 of the gate line 20 in contact with the active region 10 adjacent to the device isolation region is formed in a tab shape having a large width, in order to reduce the leakage current generated at the end portion 30 of the gate line 20 in the peripheral circuit region due to the HEIP effect when a voltage is applied from the source to the drain of the transistor.

However, an additional space for a tab is required to form the end portion 30 of the gate line 20 in a tab shape having a large width, whereby the entire size of the device chip increases. Thus, integration of the device deteriorates.

### BRIEF SUMMARY OF THE INVENTION

In one aspect, the invention provides a transistor capable of minimizing leakage current generated at an end portion of a gate line disposed adjacent to a device isolation layer by forming the end portion into a stepped portion and increasing a length of a channel.

In another aspect, the invention provides a method for manufacturing a transistor capable of minimizing leakage current generated at an end portion of a gate line disposed adjacent to a device isolation layer by increasing the length of a channel.

In accordance with one aspect of the invention, a transistor comprises: a semiconductor substrate including an active region defined by a device isolation layer; gate lines spaced specified intervals on the active region of the semiconductor substrate; and trenches of a valley structure etched to a specified depth in the semiconductor substrate in contact with end portions of the gate lines.

In the transistor, the trenches of the valley structure are preferably formed in a rectangular shape and disposed in the end portions of the active region of the semiconductor substrate. Further, preferably, the trenches of the valley structure are disposed adjacent to the device isolation layer.

Preferably, the end portions of the gate lines have a T-shaped cross section.

The transistor preferably further includes contact regions formed at both sides of the gate lines.

At least one of the gate lines is preferably included in a NMOS transistor or PNOS transistor in a peripheral circuit region.

In accordance with another aspect of the invention, a transistor comprises: a semiconductor substrate including an active region defined by a device isolation layer; gate lines spaced specified intervals on the active region of the semiconductor substrate; and protrusions of a mesa structure protruding a specified height from a surface of the semiconductor substrate in portions in contact with end portions of the gate lines.

In the transistor, the protrusions of the mesa structure are preferably formed in a rectangular shape and disposed in end portions of the active region of the semiconductor substrate. Further, the protrusions of the mesa structure are preferably disposed adjacent to the device isolation layer.

Preferably, the end portions of the gate lines have an inverted U-shaped cross section with the recess in the cross section facing the semiconductor substrate.

The transistor preferably further includes contact regions formed at both sides of the gate lines.

At least one of the gate lines is preferably included in a NMOS transistor or PMOS transistor in a peripheral circuit region.

In accordance with yet another aspect of the invention, a method for manufacturing a transistor comprises: forming a device isolation layer in a semiconductor substrate including a cell region and a peripheral circuit region; forming a trench of a valley structure in an end portion of an active region in the peripheral circuit region; and forming a gate line engaging the trench of the valley structure.

In the method of manufacturing a transistor, forming a trench of a valley may preferably include forming a photoresist fill pattern to cover the cell region of the semiconductor substrate and expose the active region adjacent to the device isolation layer in the peripheral circuit region; and etching the exposed region in the peripheral circuit region through a mask of the photoresist film pattern to form the trench of the valley structure.

Forming a trench of a valley preferably includes forming a photoresist film pattern to expose an region for forming a recessed channel in the cell region of the semiconductor substrate and expose the active region adjacent to the device isolation layer in the peripheral circuit region; and performing an etching process using a mask of the photoresist film pattern to form a recessed channel trench in the cell region and the trench of the valley structure in the peripheral circuit region.

Preferably, the trench of the valley structure is preferably formed in a rectangular shape and disposed adjacent to the device isolation layer.

Preferably, the end portion of the gate line has a T-shaped cross section.

In accordance with yet another aspect of the invention, a method for manufacturing a transistor comprises: forming a device isolation layer in a semiconductor substrate including a cell region and a peripheral circuit region; forming a protrusion of a mesa structure having a flat top surface in an end portion of an active region in the peripheral circuit region; and forming a gate line engaged with the protrusion of the mesa structure.

In the method of manufacturing a transistor, forming a protrusion of a mesa structure preferably includes forming a photoresist film pattern to cover the cell region of the semiconductor substrate and expose the active region adjacent to the device isolation layer in the peripheral circuit region; and etching the exposed region in the peripheral circuit region through a mask of the photoresist film pattern to form the protrusion of the mesa structure.

Forming a protrusion of a mesa structure preferably includes forming a photoresist film pattern to expose an region for forming a fin type protrusion in the cell region of the semiconductor substrate and expose the active region adjacent to the device isolation layer in the peripheral circuit region; and performing an etching process using a mask of the photoresist film pattern to form the fin type protrusion in the cell region and the protrusion of the mesa structure in the peripheral circuit region.

Preferably, the protrusion of the mesa structure is formed in a rectangular shape and disposed adjacent to the device isolation layer.

Preferably, the end portion of the gate line has an inverted U-shaped cross section.

### BRIEF DESCRIPTION OF THE DRAWINGS

The above and other objects, features and other advantages of the invention will be moire clearly understood from the following detailed description taken in conjunction with the accompanying, drawings, in which:

FIGS. 1A to 1C are diagrams for explaining a conventional transistor;

FIG. 2 is a diagram for explaining a structure of a transistor configured according to the invention;

FIGS. 3 to 6 are diagrams for explaining an end portion of a gate line in a cell region and a peripheral circuit region.

FIG. 7 shows a cross sectional view of the gate line; and

FIGS. 8A to 11C are diagrams for a method for manufacturing a transistor in accordance with embodiments of the present invention.

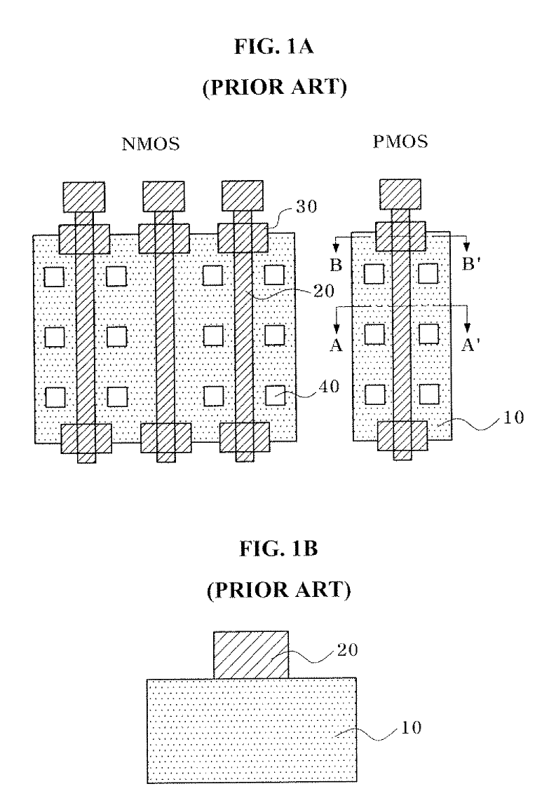

### DETAILED DESCRIPTION OF THE INVENTION

Preferred embodiments of the invention will now be described in detail with reference to the accompanying drawings. These embodiments are used only for illustrative purposes, and the invention is not limited thereto.

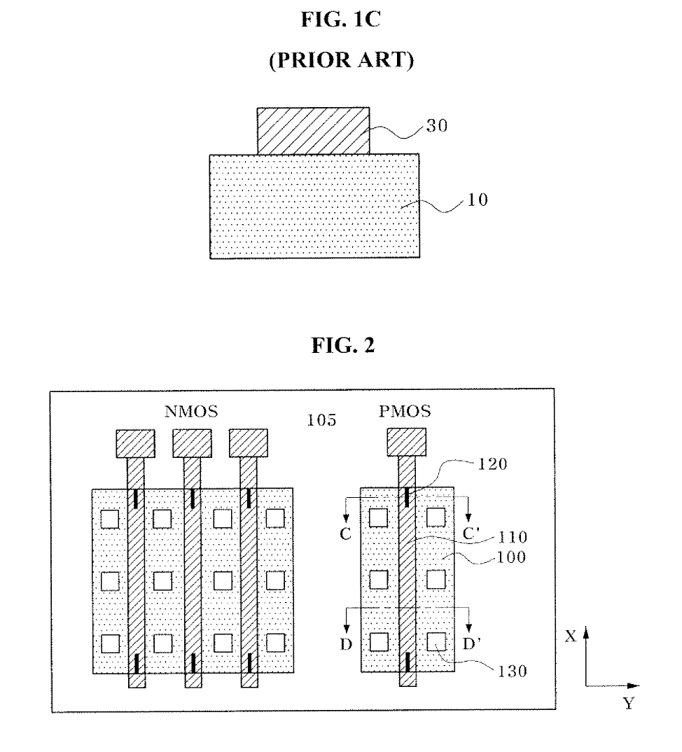

FIG. 2 is a diagram for explaining a structure of a transistor configured according to the invention.

Referring to FIG. 2, the transistor configured according to the invention includes gate lines 110 disposed at specified intervals on an active region 100 of a semiconductor substrate. An end portion 120 of each gate line 110 disposed on the active region 100 of the semiconductor substrate adjacent to a device isolation region 105 engages a trench of a valley structure etched to a specified depth or a protrusion of a mesa structure protruded to a specified height. Here, the transistor includes a NMOS transistor and a PMOS transistor in a peripheral circuit region. The device isolation region 105 is a remaining region except for the active region 100, and the device isolation region 105 and the active region 100 are separated by a device isolation layer (not shown) such as a shallow trench isolation (STI). In the drawings, “X” designates a direction in which the gate line is extended and “Y” designates a direction perpendicular to the X direction.

Further, although not shown in the drawing, spacers are formed at both side walls of the gate line 110, and source/drain regions are formed in the active region 100 of the substrate exposed at both sides of the gate line 110. Further, contact electrodes 130 are formed on the active region 100 such that the contact electrodes 130 are vertically connected to the source/drain regions.

The end portion 120 of the gate line 110 may have a T-shaped cross section due to the trench of the valley structure formed in the active region 100 of the semiconductor substrate adjacent to the device isolation region. Further, the end portion 120 of the gate line 110 may have an inverted U-shaped cross section) wherein the recess in the cross section faces the substrate, due to the protrusion of the mesa structure formed in the active region 100 of the semiconductor substrate adjacent to the device isolation region.

In the transistor according to the invention, the end portion 120 of the gate line in contact with the active region 100 of the semiconductor substrate is formed to have a width equal to the line width of the gate lines 110 formed on the active region 100. The end portion 120 of the gate line 110 has a T-shaped cross section or an inverted U-shaped cross section with the recess in the cross section facing the substrate, due to the trench of the valley structure or the protrusion of the mesa structure formed in the active region. Accordingly, a channel of the gate line can be longer than that of the conventional gate line. Thus, all gate lines can be designed to have the same line width while reducing leakage current generated at the end portion of each gate line due to the HEIP effect when a voltage is applied from a source to a drain of the transistor.

Hereinafter, an end portion of a gate line in a cell region and a peripheral circuit region will be described.

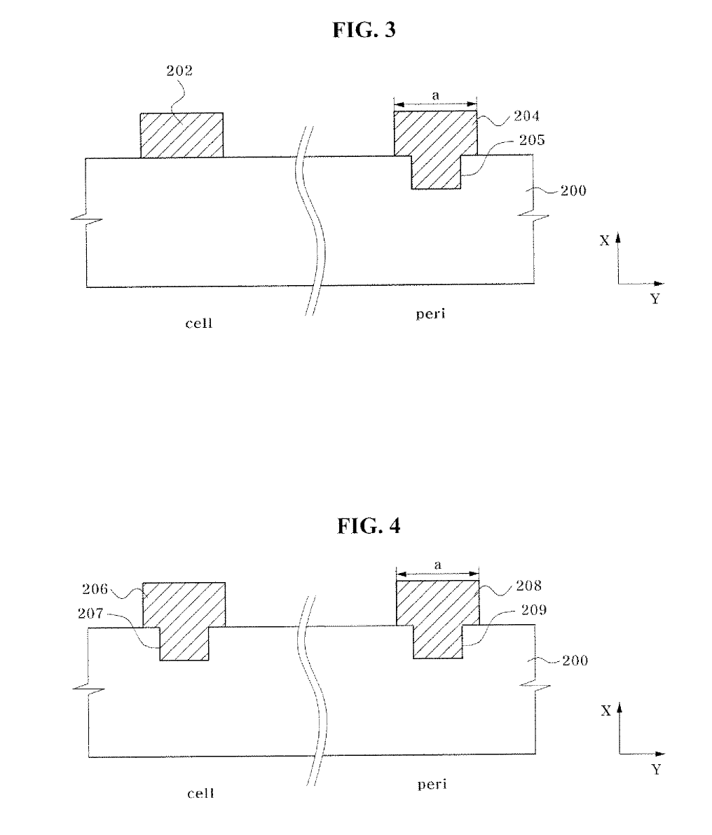

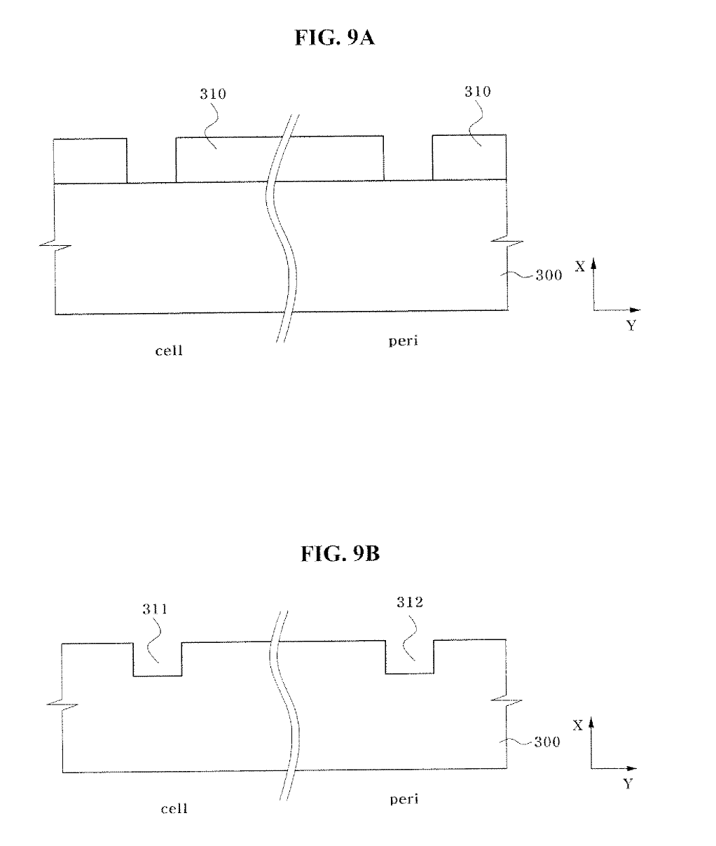

FIGS. 3 to 6 show cross sectional views of the peripheral circuit region taken along lines C-C′ in FIG. 2. FIG. 7 shows a cross sectional view of the gate line in the peripheral circuit region taken along lines D-D′.

Referring to FIG. 3, a first gate line structure of the transistor according to the invention includes a gate line 202 that is formed to have a flat bottom surface on a semiconductor substrate 200, in the cell region. The first gate line structure also includes a gate line 204 in the peripheral circuit region including NMOS and PMOS regions, wherein an end portion of the gate line 204 engages a trench 205 of the valley structure that is formed in an active region of the semiconductor substrate 200 adjacent to the device isolation region by etching the substrate to a specified depth from the surface thereof. Further, “X” designates a direction in which the gate line is extended and “Y” designates a direction perpendicular to the X direction. Hereinafter, description of the X and Y directions will be omitted.

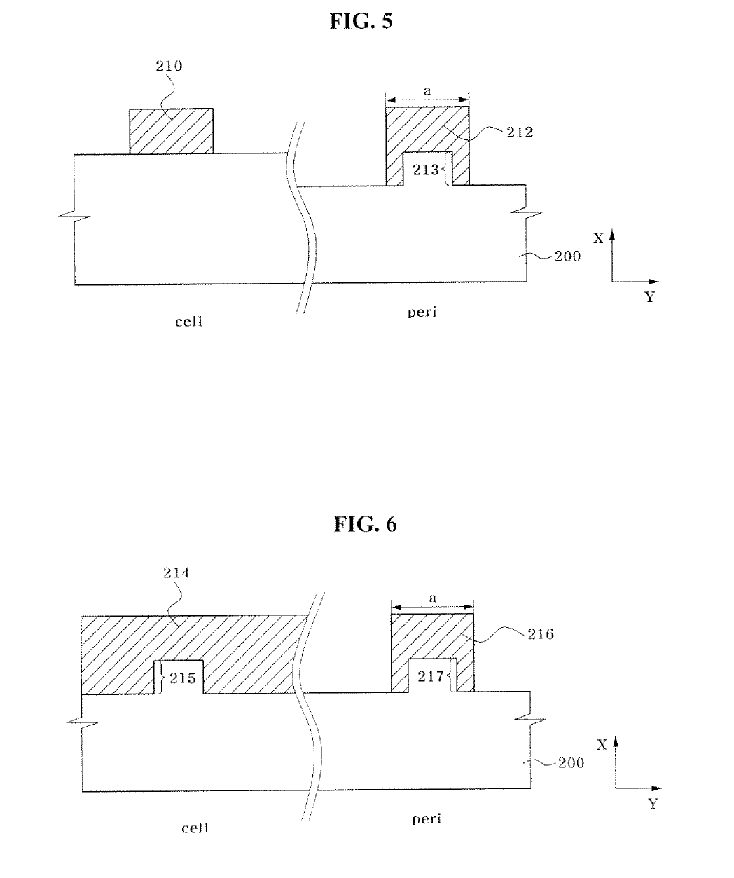

Referring to FIG. 4, a second gate line structure of the transistor according to the invention includes t gate line 206 engages a trench 207 for a recessed channel formed by etching the substrate to a specified depth from the surface thereof, in the cell region. The second gate line structure also includes a gate line 208 in the peripheral circuit region, wherein an end portion of the gate line 208 engages a trench 209 of the valley structure that is formed in the active region of the semiconductor substrate 200 adjacent to the device isolation layer by etching the substrate to a specified depth from the surface thereof.

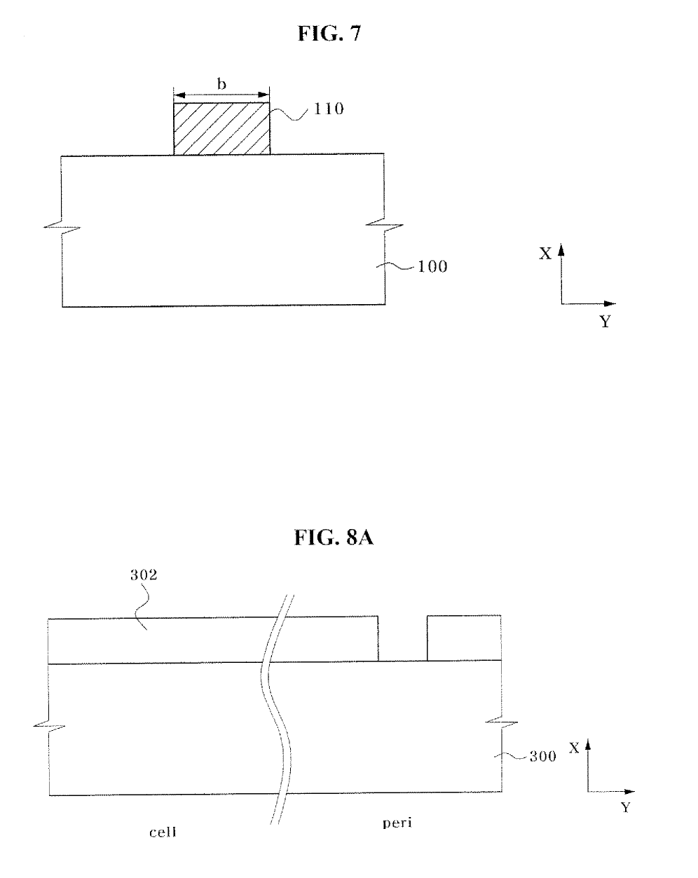

Referring to FIG. 5, a third gate line structure of the transistor according to the invention includes a gate line 210 that is formed to have a flat bottom surface on the active region of the semiconductor substrate 200 adjacent to the device isolation layer and an end portion of the gate line, in the cell region. The third gate line structure also includes a gate line 212 in the peripheral circuit region including NMOS and PMOS regions, wherein an end portion of the gate line 212 is engaged with a protrusion 213 of the mesa structure that is formed on the active region of the semiconductor substrate 200 adjacent to the device isolation layer to be protruded to a specified height from the surface of the substrate.

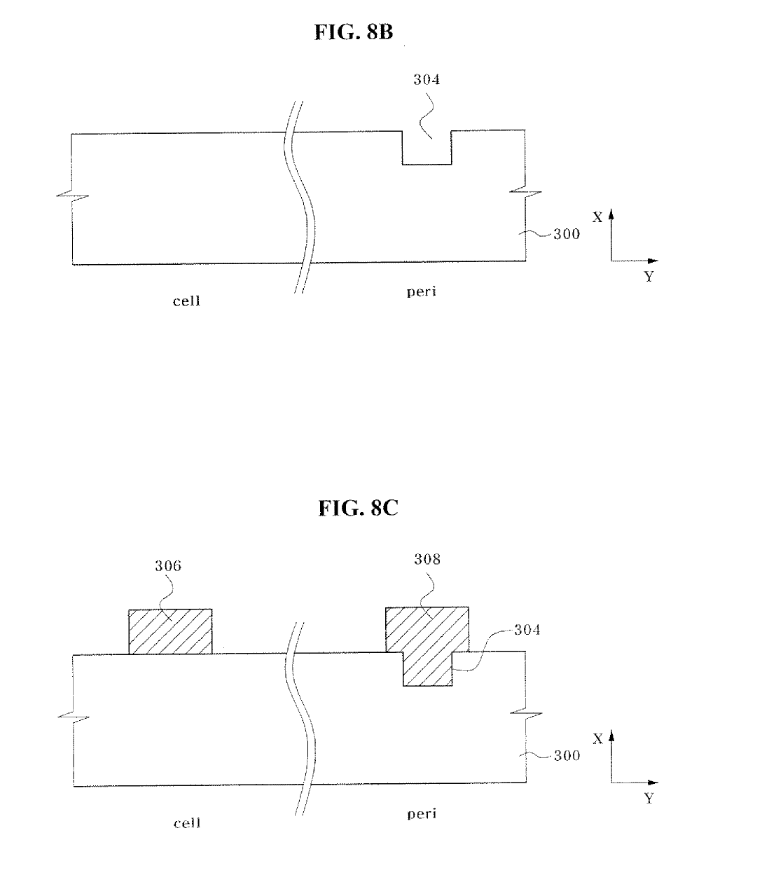

Referring to FIG. 6, a fourth gate line structure of the transistor according to the present invention includes a gate line 214 that is engaged with a protrusion 215 protruded to a specified height from the surface of the semiconductor substrate 200, in the cell region. The fourth gate line structure also includes a gate line 216 in the peripheral circuit region including NMOS and PMOS regions, wherein an end portion of the gate line 216 engages a protrusion 217 of the mesa structure having a flat top surface that is formed on the active region of the semiconductor substrate 200 adjacent to the device isolation layer to be protruded to a specified height from the surface of the substrate.

As shown in FIGS. 3 to 6, in the peripheral circuit region, the end portions of the gate lines of the transistor are formed to be engaged with the trenches 205 and 209 of the valley structure or the protrusions 213 and 217 of the mesa structure. As a result, the end portion of the gate line can be formed to have the same line width a as the line width b of the gate line 110 shown in FIG. 7.

Hereinafter, a method for manufacturing the transistor according to the invention will be described in accordance with embodiments of the invention.

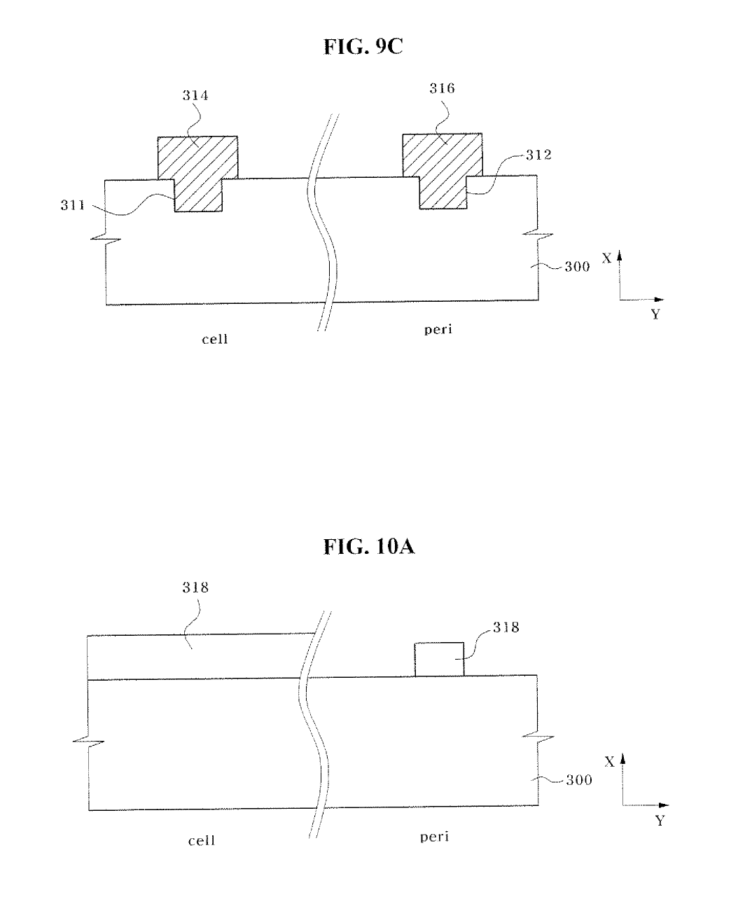

FIGS. 8A to 8C are diagrams for a method for manufacturing a transistor, wherein an end portion of a gate line is engaged with a trench of the valley structure in accordance with a first embodiment of the invention.

Referring to FIG. 5A, a photoresist film pattern 302 is formed on a semiconductor substrate 300 including a device isolation region to cover the substrate 300 in the cell region and selectively expose the substrate 300 in the peripheral circuit region. In the peripheral circuit region, it is preferable to expose only a region adjacent to the device isolation region to be engaged with the end portion of the gate line.

Referring to FIG. 8B, in the peripheral circuit region, the exposed region to be engaged with the end portion of the gate line is etched through a mask of the photoresist film pattern 302, so that a trench 304 of the valley structure is formed. The trench 304 of the valley structure may be formed in a rectangular shape.

Then, as shown in FIG. 8C, gate lines 306 and 308 disposed at specified intervals are formed by depositing and patterning a gate insulating film (not shown) and a gate electrode on the semiconductor substrate 300. Specifically, the gate line 306 having a flat bottom surface is formed in the cell region, and the gate line 308 is formed in the peripheral circuit region, wherein an end portion of the gate line 308 is engaged with the trench 304 of the valley structure adjacent to the device isolation region. The end portion of the gate line 308 has a T-shaped cross section due to the trench 304 of the valley structure formed on the semiconductor substrate. Further, “X” designates a direction in which the gate line is extended and “Y” designates a direction perpendicular to the X direction. Hereinafter, description of the X and Y directions will be omitted.

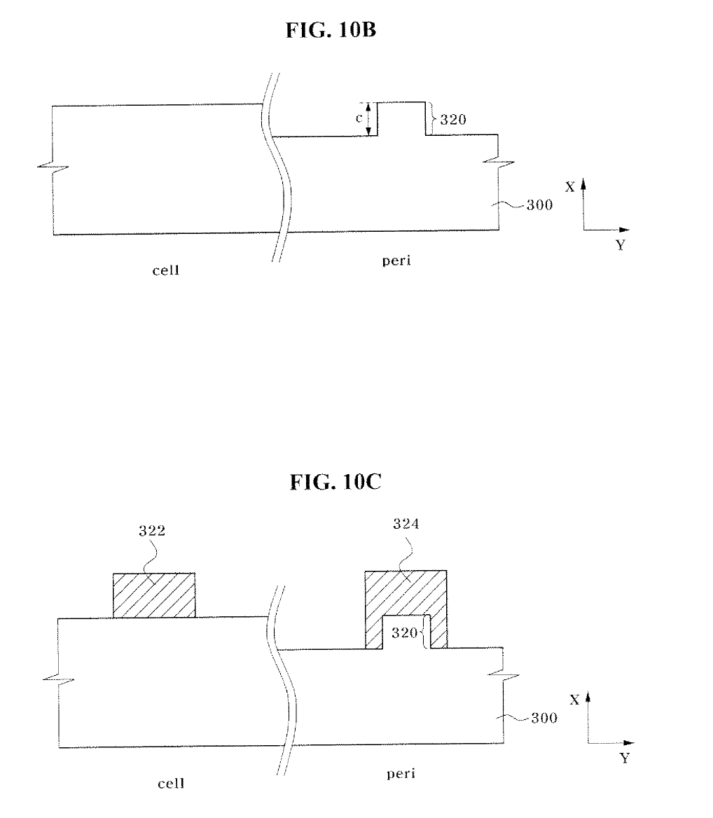

FIGS. 9A to 9C are diagrams for a method for manufacturing a transistor, wherein an end portion of a gate line is engaged with a trench of the valley structure in accordance with a second embodiment of the invention.

Referring to FIG. 9A, a photoresist film pattern 310 is formed on the semiconductor substrate 300 including the device isolation region to selectively expose the substrate 300 in the cell region and the peripheral circuit region. In this case, exposed regions in the cell region and the peripheral circuit region are regions for forming a recessed channel trench and a trench, respectively. In the peripheral circuit region, it is preferable to expose only an active region of the semiconductor substrate 300 to be engaged with the end portion of the gate line, adjacent to the device isolation region.

Referring to FIG. 9B, the exposed regions in the cell region and the peripheral circuit region are etched through a mask of the photoresist film pattern 310, so that trenches 311 and 312 of the valley structure are formed. The trench 312 of the valley structure may be formed in a rectangular shape.

Then, as shown in FIG. 9C, gate lines 314 and 316 disposed at specified intervals are formed by depositing and patterning a gate insulating film (not shown) and a gate electrode on the semiconductor substrate 300. Specifically, the gate line 314 for a recessed channel is formed in the cell region, and the gate line 316 is formed in the peripheral circuit region, wherein an end portion of the gate line 316 is engaged with the trench 312 of the valley structure adjacent to the device isolation region. The end portion of the gate line 316 formed in the peripheral circuit region has a T-shaped cross section due to the trench 312 of the valley structure. In this case, while the trench 311 for a recessed channel is formed in the cell region, the trench 312 of the valley structure is formed at the same time in the peripheral circuit region, whereby the number of steps in a photolithography process can be reduced.

As described above, in the peripheral circuit region the end portion of the gate line engages the trench of the valley structure, which is formed in the active region of the semiconductor substrate adjacent to the device isolation region. Accordingly, the channel can be lengthened while the end portion of the gate line is formed to have the same line width as the gate line width. Thus, an interval between neighboring gate lines can be further shortened, thereby improving integration of the device. Further, since the end portion of the gate line adjacent to the device isolation region is formed to have the same line width as the gate line width, it is possible to prevent a contact between tabs and improve characteristics of the device.

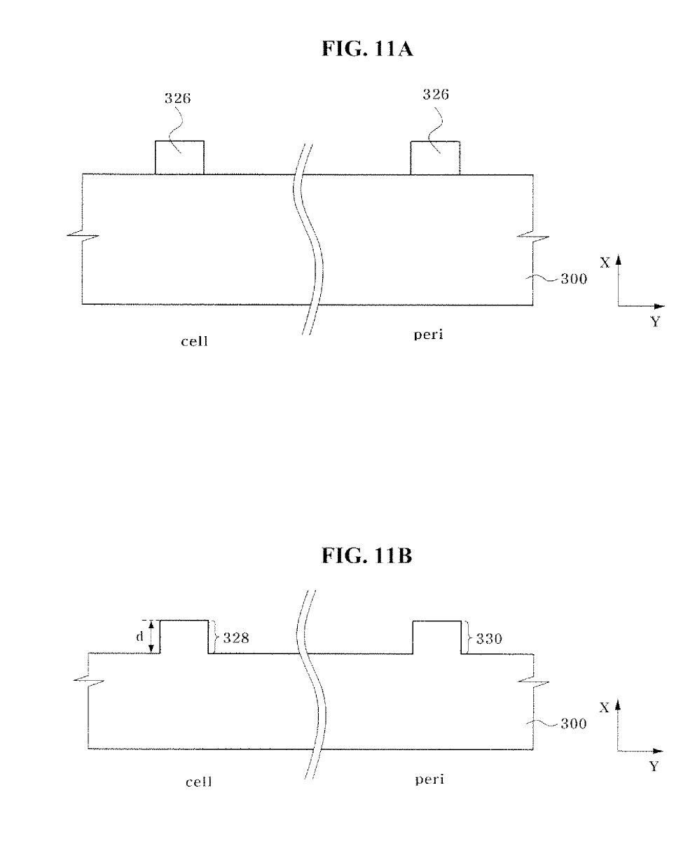

FIGS. 10A to 10C are diagrams for a method for manufacturing a transistor, wherein an end portion of a gate line engages a protrusion of the mesa structure in accordance with a third embodiment of the invention.

Referring to FIG. 10A, a photoresist film pattern 318 is formed on the semiconductor substrate 300 including the device isolation region to cover the substrate 300 in the cell region and selectively cover the substrate 300 in the peripheral circuit region. In the peripheral circuit region, it is preferable to cover only an active region of the semiconductor substrate 300 adjacent to the device isolation region to be engaged with the end portion of the gate line.

Referring to FIG. 10B, in the peripheral circuit region, an exposed region in the peripheral circuit region is etched through a mask of the photoresist film pattern 318, so that a protrusion 320 of the mesa structure having a flat top surface is formed to be protruded from the surface of the substrate. The protrusion 320 of the mesa structure may be formed in a rectangular shape. In this case, the protrusion 320 of the mesa structure can be formed by etching the semiconductor substrate 300 to a specified depth c from the surface thereof.

Then, as shown in FIG. 10C, gate lines 322 and 324 disposed at specified intervals are formed by depositing and patterning a gate insulating film (not shown) and a gate electrode on the semiconductor substrate 300. An end portion of the gate line 324 has an inverted U-shaped cross section, wherein the recess in the cross section faces the semiconductor substrate 300.

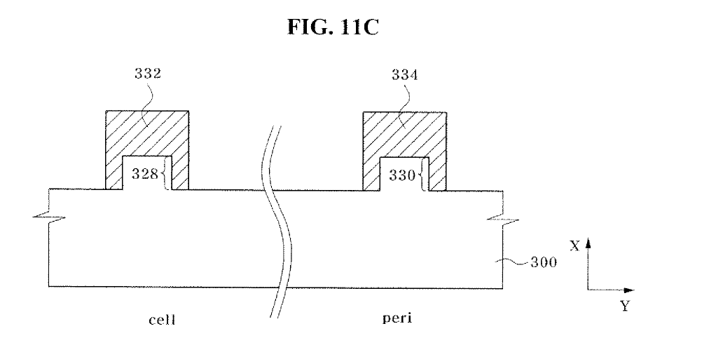

FIGS. 11A to 11C are diagrams for a method for manufacturing a transistor, wherein an end portion of a gate line engages a protrusion of the mesa structure in accordance with a fourth embodiment of the invention.

Referring to FIG. 11A, a photoresist film pattern 326 is formed on a semiconductor substrate 300 including the device isolation region to selectively cover the substrate 300 in the cell region and the peripheral circuit region. In the peripheral circuit region, it is preferable to cover only an active region of the semiconductor substrate 300 to be engaged with the end portion of the gate line, adjacent to the device isolation region.

Referring to FIG. 11B, an exposed region in the cell region and the peripheral circuit region is etched through a mask of the photoresist film pattern 326, so that a protrusion 328 of a fin type is formed in the cell region, and a protrusion 330 of the mesa structure having a flat top surface is formed in the peripheral circuit region to be protruded from the surface of the substrate. The protrusion 330 of the mesa structure may be formed in a rectangular shape. In this case, the protrusion 330 of the mesa structure can be formed by etching the semiconductor substrate 300 to a specified depth d from the surface thereof.

Then, as shown in FIG. 11C, gate lines 332 and 334 disposed at specified intervals are formed by depositing and patterning a gate insulating film and a gate electrode on the semiconductor substrate 300. Specifically, the gate line 332 for a fin channel is formed in the cell region, and the gate line 334 is formed in the peripheral circuit region, wherein an end portion of the gate line 334 has an inverted U-shaped cross section due to the protrusion 330 of the mesa structure formed on the semiconductor substrate 300. In this case, while the protrusion 328 for the fin channel is formed in the cell region, at the same time, the protrusion 330 of the mesa structure is formed in the peripheral circuit region, whereby the number of steps in a photolithography process can be reduced.

As described above, the end portion of the gate line adjacent to the device isolation region engages the protrusion of the mesa structure in the peripheral circuit region. Accordingly, the channel can be lengthened while the end portion of the gate line is formed to have the same line width as the gate line width. Thus, an interval between neighboring gate lines can be further shortened, thereby improving integration of the device. Further, since the end portion of the gate line adjacent to the device isolation region is formed to have the same line width as the gate line width, it is possible to prevent a contact between tabs and improve characteristics of the device.

Next, although not shown in the drawings, spacer films are formed at both side walls of the gate lines engaged with the trench of the valley structure and the protrusion of the mesa structure by depositing and patterning an insulating film such as a silicon nitride film on the gate lines. Then, source/drain regions are formed in the semiconductor substrate by performing ion implantation of n-type or p-type conductive impurities into the active region of the substrate, thereby forming a transistor.

In the method for manufacturing the transistor according to the invention, the end portion of the gate line is engaged the trench of the valley structure etched to a specified depth or the protrusion of the mesa structure protruded to a specified height that is formed in the active region of the semiconductor substrate. Since the end portion of the gate line in contact with the active region has a T-shaped cross section or an inverted U-shaped cross section with the recess in the cross section facing the substrate, due to the trench or protrusion, the channel can be longer than that of a general gate line while the end portion of the gate line in contact with the active region is formed to have the same line width as a general gate line width.

As described above, according to the invention, the trench of the valley structure or the protrusion of the mesa structure protruded to a specified height is formed in the active region in contact with the end portion of the gate line, whereby the channel can be longer than that of a general gate line while the end portion of the gate line in contact with the active region is formed to have the same line width as a general gate line width.

Therefore, by forming the trench of the valley structure or the protrusion of the mesa structure protruded to a specified height according to the invention, it is possible to reduce the leakage current generated at an interface of the end portion of the gate line due to the HEIP effect when a voltage is applied from the source to the drain of the transistor. Further, all gate lines can be designed to have the same line width, thereby preventing the size of a semiconductor device chip from increasing. Furthermore, it is possible to secure stability of threshold voltage under the gate line by forming the gate line having an equal line width.

Although the preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A transistor comprising:
a semiconductor substrate including an active region defined by a device isolation layer;
gate lines spaced specified intervals on the active region of the semiconductor substrate; and
trenches of a valley structure etched to a specified depth in end portions of the active region of the semiconductor substrate in contact with end portions of the gate lines.

2. The transistor according to claim 1, wherein the trenches of the valley structure are formed in a rectangular shape.

3. The transistor according to claim 1, wherein the gate lines have end portions having a T-shaped cross section.

4. The transistor according to claim 1, further comprising: contact regions formed at both sides of the gate lines.

5. The transistor according to claim 1, wherein at least one of the gate lines is included in a NMOS transistor or PMOS transistor in a peripheral circuit region.

6. A transistor comprising:
a semiconductor substrate including an active region defined by a device isolation layer;
gate lines spaced specified intervals on the active region of the semiconductor substrate; and
protrusions of a mesa structure protruding to a specified height from a surface of the semiconductor substrate in end portions of the active region of the semiconductor substrate in contact with end portions of the gate lines.

7. The transistor according to claim 6, wherein the protrusions of the mesa structure are formed in a rectangular shape.

8. The transistor according to claim 6, wherein the gate lines have end portions having an inverted U-shaped cross section with the recess in the cross section facing the semiconductor substrate.

9. The transistor according to claim 6, further comprising:
contact regions formed at both sides of the gate lines.

10. The transistor according to claim 6, wherein at least one of the gate lines is included a NMOS transistor or PMOS transistor in a peripheral circuit region.

11. A method for manufacturing a transistor comprising:
forming a device isolation layer in a semiconductor substrate including a cell region and a peripheral circuit region;
forming a trench of a valley structure in an end portion of an active region in the peripheral circuit region; and
forming a gate line engaging the trench of the valley structure.

12. The method according to claim 11, wherein forming a trench of a valley structure includes:
forming a photoresist film pattern to cover the cell region of the semiconductor substrate and expose the active region adjacent to the device isolation layer in the peripheral circuit region; and
etching the exposed region in the peripheral circuit region through a mask of the photoresist film pattern to form the trench of the valley structure.

13. The method according to claim 11, wherein forming a trench of a valley structure includes:
forming a photoresist film pattern to expose an region for forming a recessed channel in the cell region of the semiconductor substrate and expose the active region adjacent to the device isolation layer in the peripheral circuit region; and
performing an etching process using a mask of the photoresist film pattern to form a recessed channel trench in the cell region and the trench of the valley structure in the peripheral circuit region.

14. The method according to claim 11, wherein the trench of the valley structure is formed in a rectangular shape.

15. The method according to claim 11, wherein the gate line has an end portion having a T-shaped cross section.

16. A method for manufacturing a transistor comprising:
forming a device isolation layer in a semiconductor substrate including a cell region and a peripheral circuit region;
forming a protrusion of a mesa structure having a flat top surface in an end portion of an active region in the peripheral circuit region; and
forming a gate line engaging the protrusion of the mesa structure.

17. The method according to claim 16, wherein forming a protrusion of a mesa structure includes:
forming a photoresist film pattern to cover the cell region of the semiconductor substrate and cover the active region adjacent to the device isolation layer in the peripheral circuit region; and
etching an exposed region in the peripheral circuit region through a mask of the photoresist film pattern to form the protrusion of the mesa structure.

18. The method according to claim 16, wherein forming a protrusion of a mesa structure includes:
forming a photoresist film pattern to cover an region for forming a film type protrusion in the cell region of the semiconductor substrate and cover the active region adjacent to the device isolation layer in the peripheral circuit region; and
performing an etching process using a mask of the photoresist film pattern to form the fin type protrusion in the cell region and the protrusion of the mesa structure in the peripheral circuit region.

19. The method according to claim 16, wherein the protrusion of the mesa structure is formed in a rectangular shape.

20. The method according to claim 16, wherein the gate line has an end portion having an inverted U-shaped cross section.
